(19) United States
(12) Patent Application Publication
(10) Pub. No.: US 2024/0336743 A1
(43) Pub. Date: Oct. 10, 2024

(54) METAL-PLATED LAMINATES CONTAINING POLYORGANOSILOXANES

(71) Applicant: Wacker Chemie AG, Munich (DE)

(72) Inventor: Frank Sandmeyer, Munich (DE)

(73) Assignee: Wacker Chemie AG, Munich (DE)

(21) Appl. No.: 18/294,548

(22) PCT Filed: Aug. 12, 2021
(86) PCT No.: PCT/EP2021/072479

§ 371 Date: Feb. 2, 2024

(51) Int. Cl. C08G 77/50; C08G 77/08

(52) U.S. Cl. CPC C08G 77/50; C08G 77/08

(57) ABSTRACT

A metal-clad laminate includes crosslinkable, organopolysiloxane compounds of the formula (I), [O_{3-a/2}RₐSi—Y(SiRₐO_{3-a/2})_{b}]_{c}(R¹SiO_{3/2})_{d}(R₂²SiO_{2/2})ₑ(R₃³SiO_{1/2})_{f}(SiO_{4/2})_{g} (I). Based on all SiC-bonded radicals Y, R, R¹, R², and R³ as 100 mol %, at least 0.1 mol % must be aliphatically unsaturated radicals. In the formula (I), a is 0, 1 or 2, where the indices a on either side of the group Y may assume their meaning independently of one another, such that different a may independently of one another be different values within the range of values specified, b is a number having a value from 1 to 11, c is a value from 0.1 to 0.99, d is a value from 0 to 0.8, e is a value from 0 to 0.5, f is a value from 0.01 to 0.6, and g is a value from 0 to 0.2, where c+d+e+f+g=1.

The present invention relates to metal-clad laminates comprising crosslinkable organopolysiloxane compounds.

### PRIOR ART

Copper-clad electrolaminates consist according to DIN 40802 page 2 of a layered material laminated on one or both sides with electrolytic copper foil having a purity of at least 99.5%. The laminate serves here as a support and insulation material, the copper layer for the production of the conductor tracks. Among electrolaminates, three products have become important. In these products, the laminate consists of hard paper, epoxy hard paper or epoxy resin-glass fabric.

Despite being more costly than hard paper, it is becoming increasingly common for epoxy resin-glass fabric to be used, especially in telecommunications, where higher frequencies are employed. The advantages of said electrolaminate are high mechanical strength, better electrical values when exposed to moisture, and low dielectric losses at high frequencies.

The sequence of events in the production of electrolaminates is as follows. The paper webs or fabric webs for the laminate, for example glass fiber webs, are impregnated with resin, which acts as a binder. Epoxy polyester, phenol or melamine are commonly used for this purpose. The impregnated webs are then dried, this being accompanied by precondensation of the resin to the desired degree.

With the advancing development of high-frequency technology into the GHz range for wireless communication, there is a growing demand for materials suitable for the realization thereof. This relates to all fields of materials such as copper foils, binders, glass fibers, etc. In the case of the binders, the epoxy resins traditionally used for the production of copper-clad laminates or as a result of for the production of printed circuit boards can no longer be used for GHz applications because of their overly high dielectric loss factors. Polytetrafluoroethylene, which has a very low dielectric loss factor and is thus readily employable for high-frequency uses from this point of view, has other disadvantages, in particular poor processability and poor bonding properties, which means an alternative is desirable. Polyphenylene ethers, hydrocarbon resins, and bismaleimides, and also variants such as bismaleimide triazine resins and combinations of the mentioned organic polymers, are currently being intensively researched as binders for this field of application, since they combine low dielectric loss factors with good mechanical and thermal properties and water repellency.

Polyorganosiloxanes have excellent heat resistance, weathering stability, and hydrophobicity, are flame-retardant, and have low dielectric loss factors. These property profiles qualify both polyphenylene ethers, bismaleimides, bismaleimide triazine, and hydrocarbon resins and also polyorganosiloxanes for use as binders for producing high-frequency copper-clad laminates and components, such as printed circuit boards and antennas.

It is therefore obvious both to use silicone resins as binders for these high-frequency uses and to combine the positive properties of the silicones with those of the mentioned organic polymers in order to boost their performance symbiotically. Corresponding attempts are already documented in the prior art.

In polyorganosiloxanes, neighboring silicon atoms are predominantly connected to each other via oxygen atoms. However, other ways in which neighboring silicon atoms can be connected to each other are also known, for example units bridged by organic radicals.

Organic radicals that bridge neighboring silicon atoms arise for example always as a result of a hydrosilylation reaction in which a Si—H group adds to an unsaturated organic radical attached to silicon. Such reactions are primarily known for curing a formulation that contains these two types of functional groups, after using the formulation to permanently fix an achieved application result, see for example US 2018/0370189. They can also be used for producing polyorganosiloxanes containing organic radicals bridging neighboring silicon atoms in which a species that can be processed further is formed. In these cases, the preformed silicone structures and compositions are preserved, with the formation always of block copolymer structures in which the starting structures are retained as the building block segments. A random distribution of the organic substituents bridging two silicon atoms is not possible here. In addition, the number of bridging units is limited by the number of terminal functional groups. Particularly when this approach is chosen in order to fix an already-reached end state, it should be noted that a shrinkage in volume commences as a consequence of the curing reaction, which leads to stresses in the cured matrix and limits or reduces mechanical performance. In order to be able to introduce any number of such bridging units into an organopolysiloxane structure, for example if they have a particular function for a chosen application, this route is accordingly not suitable and limits for example the invention as set out in US 2018/0370189.

U.S. Pat. No. 10,316,148 teaches organopolysiloxanes of the formula (R¹SiO_{3/2})ₐ(XR₂²SiO_{1/2})_{b}(O_{1/2}SiR₂²YR₂²SiO_{1/2})_{c}, where R¹ and R² are independently of one another C₁-C₂₀ alkyl groups, C₆-C₂₀ aryl groups or C₇-C₂₀ aralkyl groups. When X is a C₂-C₁₂ alkanediyl group or a linear Si—H functional siloxane radical containing 2-7 Si units and having a bridging C₂-C₁₂ alkanediyl group, then Y is a linear bridging siloxane group having 2-7 siloxane units, where Y is in each case incorporated into the organopolysiloxane of the invention via a bridging C₂-C₁₂ alkanediyl group. When X is a C₂-C₁₂ alkanediyl group or a Si—H-terminated siloxane radical consisting of one or two siloxane units in which the two siloxane units are connected by a bridging silphenylene radical, Y is a siloxane radical comprising two siloxane units in which the two siloxane units are connected to one another by a bridging silphenylene radical and the radical Y is in each case incorporated into the organopolysiloxane of the invention via a bridging C₂-C₁₂ alkanediyl group.

X and Y are chosen so that they result in the formation exclusively of linear structures such that block copolymer polyorganosiloxanes are in principle present in which the (R¹SiO_{3/2}) units form the three-dimensional silicone resin block and the (XR₂²SiO_{1/2})_{b}(O_{1/2}SIR₂²YR₂²SiO_{1/2})_{c} units form the linear block. Unsaturated organic radicals that could be brought to reaction by a free-radical reaction are absent. These are completely consumed in the reaction by which the polyorganosiloxanes of the invention are formed by hydrosilylation, in which the Si—H groups are used in excess, resulting in the formation of Si—H-terminated polyorganosiloxanes.

a is a number from 0.65 to 0.9, b is a number from 0.1 to 0.35, and c is a number from 0 to 0.1, where a+b+c=1.

The inventive organopolysiloxanes of this invention are produced by a hydrosilylation reaction of a polyorganosiloxane (R¹SiO_{3/2})_{d}(R⁵R₂²SiO_{1/2})ₑ, where R⁵ is an olefinically unsaturated C2-C12 alkenyl group, d a number from 0.65 to 0.9, and e a number from 0.1 to 0.35, with a linear Si—H-terminal polyorganosiloxane of the formula HR₂³SiO(R₂³SiO) nSiR₂³H or a disilylbenzene of the formula HR₂³Si—C₆H₄—SiR₂³H, where both a double or just a single hydrosilylation of the doubly Si—H-terminated siloxane components is possible.

Both the alkanediyl-bridged and the phenylene-bridged building blocks are embedded exclusively in linear segments of the polysiloxane structure, in which the silicon atoms bridged by the alkanediyl group or by the phenylene group are always attached to just one further silicon atom and are not the starting point for branching through bonds to a plurality of silicon atoms.

The polyorganosiloxanes according to U.S. Ser. No. 10/316,148 show a high refractive index, high transparency, and good processability for use in optical semiconductor elements. Because they are formed by a hydrosilylation reaction, they contain platinum as an impurity.

US 2015/0144987 teaches hydrosilylatable formulations of alkenyl-functional three-dimensional polyorganosiloxanes, linear alkenyl-functional polyorganosiloxanes, linear Si—H-terminal polyorganosiloxanes containing silphenylene groups, optionally a further linear Si—H-terminated component containing no silphenylene unit, and a hydrosilylation catalyst. After curing by hydrosilylation, the inventive formulations of this invention, like the polyorganosiloxanes from U.S. Pat. No. 10,316,148, also have both neighboring silicon atoms that are alkanediyl-bridged and ones that are phenylene-bridged. The phenylene-bridged silphenylene units are always linear polyorganosiloxane segments in which the silicon atoms bridged by the phenylene group are always attached to just one further silicon atom through a Si—O—Si linkage and are not the starting point for branching through bonds to a plurality of silicon atoms. Because of the hydrosilylation reaction, these polyorganosiloxanes too contain platinum as an impurity.

The formulations have high Abbe numbers, good color stability in optical semiconductor elements, and are used for encapsulation of same.

U.S. Pat. No. 6,072,016 teaches linear polyorganosiloxanes that contain silphenylene groups and can be crosslinked via terminal groups capable of undergoing condensation. They do not contain any Si—H functions or aliphatically unsaturated groups.

U.S. Pat. No. 6,252,100 discloses a process for producing linear organopolysiloxanes containing structural units in which two R₂Si units are connected to each other via a bifunctional α, ω-alkanediyl radical having 2 to 18 carbon atoms.

U.S. Pat. No. 6,034,225 describes linear organopolysiloxanes having aliphatically unsaturated radicals that contain inter alia at least one unit of the formula O_{1/2}R₂SiOₓYRSiO_{2/2} that optionally contains a branching point, and optionally also O_{1/2}R₂SiOₓYR₂SiO_{1/2} units that would on the other hand be purely linear. Where x=0, either a dialkylsiloxy unit is connected to an alkylsiloxy unit that is connected to two neighboring silicon atoms via oxygen atoms, or/and two dialkylsiloxy units are connected to each other via the spacer Y. Y is a bifunctional radical of the formula —(CR₂³)ₙCHR³—, where R³ is an aliphatically saturated hydrocarbon radical or H and n is zero or an integer from 1 to 7.

Organopolysiloxane compounds having active hydrogen in the form of H—Si compounds and hydrocarbon bridges between two Si atoms are described in EP 786 463 Al and also in JP 06 107 949 and U.S. Pat. No. 4,849,491.

U.S. Pat. No. 20,100,137544 teaches polyorganosiloxanes containing per molecule at least one structural unit of the general formula (I): O_{3-a/2}RₐSi—Y(SiRₐO_{3-a/2})_{b}, where R may be identical or different and is a monovalent SiC-bonded organic radical that has 1 to 30 carbon atoms and may contain one or more nitrogen and/or oxygen atoms, Y is a di- to dodecavalent organic radical that has 1 to 30 carbon atoms and may contain one or more oxygen atoms, a is 0 or 1, and b is an integer from 1 to 11.

### Objective

The present invention addresses the object of providing polyorganosiloxanes that can be crosslinked three-dimensionally under the conditions of free-radical polymerization and that have dielectric properties suitable for use as a binder for high-frequency uses. Associated requirements are that, as the pure binder, they have a dielectric loss factor at 10 Ghz of not more than 0.0040, that any fillers present which lower the dielectric loss factor are well wetted, and that they permit the production of adhesive-free prepregs.

The present invention relates to metal-clad laminates comprising crosslinkable, i.e. curable, organopolysiloxane compounds of the formula (I)

[O_{3-a/2}RₐSi—Y(SiRₐO_{3-a/2})_{b}]_{c}(R¹SiO_{3/2})_{d}(R₂²SiO_{2/2})ₑ(R₃³SiO_{1/2})_{f}(SiO_{4/2})_{g} (I)
where R may be identical or different and is either a hydrogen radical or a monovalent SiC-bonded organic hydrocarbon radical having 1 to 18 carbon atoms and optionally substituted with heteroatoms, which may also be an unsaturated hydrocarbon radical,
Y is a divalent to dodecavalent organic organic radical having 1 to 24 carbon atoms and optionally substituted with heteroatoms, where the radical Y is always attached by a Si—C bond to the silicon atoms connected to each other by the radical Y,
R¹ is independently of one another a hydrogen radical or a preferably SiC-bonded unsaturated C1-C18 hydrocarbon radical that may optionally be substituted with heteroatoms and that optionally may also be attached to the silicon atom via an oxygen atom, where the radicals R¹ may each assume their meaning independently of one another, such that a plurality of radicals R¹ in the organopolysiloxane according to formula (I) may be different radicals from the defined group,
the radicals R² and R³ are independently of one another a hydrogen radical or an optionally unsaturated SiC-bonded C1-C18 hydrocarbon radical that may optionally be substituted with heteroatoms, or a C1-C12 hydrocarbon radical that optionally contains heteroatoms and is attached via an oxygen atom, where the radicals R² and the radicals R³ may each assume their meaning independently of one another, such that a plurality of radicals R² or a plurality of radicals R³ attached to the same silicon atom may be different radicals from the defined group,
where, based on all SiC-bonded radicals Y, R¹, R², and R³ as 100 mol %, at least 0.1 mol %, preferably at least 3 mol %, more preferably at least 5 mol % especially at least 7 mol %, must be aliphatically, i.e. olefinically or acetylenically, unsaturated radicals,
a is 0, 1 or 2, where the indices a on either side of the group Y may assume their meaning independently of one another, such that different a may independently of one another be different values within the range of values specified,
b is a number having a value from 1 to 11, preferably 1,
c is a value from 0.1 to 0.99, preferably from 0.2 to 0.98, more preferably from 0.25 to 0.8, especially from 0.3 to 0.8,
d is a value from 0 to 0.8, preferably from 0.1 to 0.7, more preferably from 0.1 to 0.6, especially from 0.1 to 0.5,
e is a value from 0 to 0.5, preferably from 0 to 0.2,
f is a value from 0.01 to 0.6, and
g is a value from 0 to 0.2, where
c+d+e+f+g=1.

The organopolysiloxane compounds of the formula (I) serve as binders and/or as adhesion promoters for the metal-clad laminates. The organopolysiloxane compounds of the formula (I) undergo crosslinking prior to use of the laminates. The laminates are preferably metal-clad laminates. The laminates are preferably used in electronic components, preferably in high-frequency uses, most preferably those operated at frequencies of 1 GHz and above.

Surprisingly, it was found that suitable polyorganosiloxanes bearing unsaturated organic functional groups or formulations thereof are particularly well suited for this purpose, which, besides regular siloxane units connected by oxygen atoms, also contain building blocks in which neighboring silicon atoms are connected to each other not by oxygen atoms, but are bridged by bridging alkylene, aralkylene or arylene units attached on either side by Si—C bonds, provided that polar, heteroatom-substituted groups on the polyorganosiloxane are at the same time avoided, i.e. are as far as possible reduced by appropriate state-of-the-art measures, including in particular alkoxy groups and silanol groups.

Polar groups such as alkoxy groups, especially those having short alkyl groups and silanol groups, themselves have relatively high dielectric loss factors and make an additional contribution to increasing the dielectric loss factor by forming points of attack for moisture.

The difference in electronegativity between silicon and oxygen according to the Allred-Rochow electronegativity scale is 1.76, which is 1 greater than the difference in electronegativity between silicon and carbon according to the same table and means that the Si—C bond has lower polarity than the Si—O bond. It is therefore to be expected that replacing Si—O bonds by Si—C bonds will help reduce the overall polarity of organopolysiloxanes and thus help reduce the dielectric loss factor of corresponding components. The more Si—O bonds that can be replaced by Si—C bonds, the more pronounced this effect. Reducing the polarity in the organopolysiloxane backbone, for example by introducing Si—C bonds instead of Si—O bonds, thus makes a significant contribution to the broad usability of such organopolysiloxanes.

Since polydiorganosiloxanes, being oils, have no binder character, they are not suitable as binders for metal-clad composites. US 2018/0370189 accordingly describes the use also of silicone resins as binders, with silicone oils used purely to adjust their viscosity, and curing to form block copolymers. The actual binder is however the silicone resin, not the silicone oil. However, there are no suggestions therein of the targeted tailoring and optimization of the employed silicone resins for the use described in US 2018/0370189, since the possibilities that exist for this were clearly not recognized.

The present invention is an improvement on the prior art according to US 2018/0370189 and develops it further, since, in order to be able to utilize the effect of the reduced polarity of the siloxane backbone in a targeted manner, it is insufficient to allow SiC-bonded organic radicals bridging neighboring silicon atoms to form solely through the curing of any Si—H groups and Si-olefin groups present by hydrosilylation at the end of an application process. The associated shrinkage in volume caused by the addition reaction according to US 2018/0370189 sets overly narrow limits on the properties-based use of this option.

The organopolysiloxane compounds of the formula (I) have a dielectric loss factor at 10 GHz of not more than 0.0040.

The organopolysiloxane compounds of the formula (I) include in the context of the present invention both polymeric and oligomeric organosiloxanes.

In particular, structures of the formula (Ia) are also included,

[O_{3-a/2}RₐSi—Y(SiRₐO_{3-a/2})_{b}]_{c}(R₃³SiO_{1/2})_{f} (Ia)

for which d, e, and g are in each case 0. This limit structure is within the scope of the invention and intended therewith. The proportion therein of SiC-bonded bridging organic radicals is particularly high and the structure is completed practically only by the terminating units (R₃³SiO_{1/2})_{f}. In a preferred embodiment of (Ia), a has a value of 2. Everything stated above for R, R³, a, b, and c is valid for (Ia) too.

Examples for R, R¹, R², and R³ are saturated or unsaturated hydrocarbon radicals that may contain aromatic or aliphatic double bonds, for example alkyl radicals, such as the methyl, ethyl, n-propyl, isopropyl, n-butyl, isobutyl, tert-butyl, n-pentyl, isopentyl, neopentyl, and tert-pentyl radical, hexyl radicals, such as the n-hexyl radical, heptyl radicals, such as the n-heptyl radical, octyl radicals, such as the n-octyl radical, and isooctyl radicals, such as the 2,2,4-trimethylpentyl and 2-ethylhexyl radical, nonyl radicals, such as the n-nonyl radical, decyl radicals, such as the n-decyl radical, dodecyl radicals, such as the n-dodecyl radical, tetradecyl radicals, such as the n-tetradecyl radical, hexadecyl radicals, such as the n-hexadecyl radical, and octadecyl radicals, such as the n-octadecyl radical, cycloalkyl radicals, such as the cyclopentyl, cyclohexyl, and 4-ethylcyclohexyl radical, cycloheptyl radicals, norbornyl radicals, and methylcyclohexyl radicals, aryl radicals, such as the phenyl, biphenyl, naphthyl, anthryl, and phenanthryl radical, alkaryl radicals, such as o-, m-, p-tolyl radicals, xylyl radicals, and ethylphenyl radicals, aralkyl radicals, such as the benzyl radical, alkenyl radicals, such as the 7-octenyl, 5-hexenyl, 3-butenyl, allyl, and vinyl radical, and also the alpha- and β-phenylethyl radical.

Preferred heteroatoms that may be present in the radicals R, R¹, R², and R³ are oxygen atoms. In addition, nitrogen atoms, phosphorus atoms, sulfur atoms, and halogen atoms, such as chlorine atoms and fluorine atoms, are also possible. Examples of preferred heteroatom-containing organic radicals R, R¹, R², and R³ are radicals containing acryloyloxy or methacryloyloxy radicals respectively of acrylic acid and methacrylic acid or the acrylic or methacrylic esters of unbranched or branched alcohols having 1 to 15 carbon atoms. Among such radicals, preference is given to those derived from methyl acrylate, methyl methacrylate, ethyl acrylate, ethyl methacrylate, propyl acrylate, propyl methacrylate, n-butyl acrylate, n-butyl methacrylate, isobutyl acrylate, isobutyl methacrylate, t-butyl acrylate, t-butyl methacrylate, 2-ethylhexyl acrylate, and norbornyl acrylate. Particular preference is given to methyl acrylate, methyl methacrylate, n-butyl acrylate, isobutyl acrylate, t-butyl acrylate, 2-ethylhexyl acrylate, and norbornyl acrylate.

These radicals are preferably not attached directly to the silicon atom, but are attached via a hydrocarbon spacer that can contain 1 to 12 carbon atoms, preferably contains 1 or 3 carbon atoms, and does not contain any further heteroatoms other than the heteroatoms present in the acryloyloxy or methacryloyloxy radical.

Further preferred heteroatom-containing radicals R, R¹, R², and R³ are those of the formula (II).

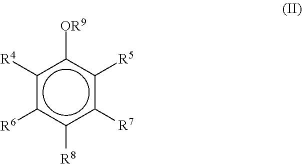

Preferably, the hydrocarbon radicals R, R¹, R², and R³ are selected from methyl, phenyl, vinyl, acryloyloxy, and methacryloyloxy radicals and the acrylic esters or methacrylic esters of unbranched or branched alcohols having 1 to 15 carbon atoms.

In formula (II), R⁴, R⁵, R⁶, R⁷, R⁸, and R⁹ are independently of one another a hydrogen radical, a hydrocarbon group or a heteroatom-substituted hydrocarbon group, where at least one of the radicals R⁴, R⁵, R⁶, R⁷ or R⁸ is a hydrocarbon group attached to the silicon atom via a Si—C or a Si—O—C bond, it being preferable that said hydrocarbon group via which the radical of the formula (II) is attached to a silicon atom is a C3 hydrocarbon group that contains no heteroatoms. Alternatively, the radical R⁴, R⁵, R⁶, R⁷ or R⁸ may also be a chemical bond, such that the radical of the formula (II) is attached directly to the silicon atom through a Si—C bond via said radical representing a chemical bond.

Examples of radicals R⁴, R⁵, R⁶, R⁷, R⁸ or R⁹ are the hydrogen radical, saturated hydrocarbon radicals, such as the methyl, ethyl, n-propyl, and isopropyl radical, the primary, secondary, and tertiary butyl radical, the hydroxyethyl radical, aromatic radicals, such as the phenylethyl radical, the phenyl radical, the benzyl radical, the methylphenyl radical, the dimethylphenyl radical, the ethylphenyl radical, heteroatom-containing radicals, such as the hydroxymethyl radical, the carboxyethyl radical, the methoxycarbonylethyl radical and the cyanoethyl radical, and acrylate and methacrylate radicals, such as methyl acrylate, methyl methacrylate, ethyl acrylate, ethyl methacrylate, propyl acrylate, propyl methacrylate, n-butyl acrylate, n-butyl methacrylate, isobutyl acrylate, isobutyl methacrylate, t-butyl acrylate, t-butyl methacrylate, 2-ethylhexyl acrylate, and norbornyl acrylate, and olefinically or acetylenically unsaturated hydrocarbon radicals.

It is optionally also possible for the neighboring radicals R⁴ and R⁶ and neighboring radicals R⁵ and R⁷ to be connected to each other to form the same cyclic saturated or unsaturated radical, thus giving rise to fused polycyclic structures.

Examples of phenol radicals of the formula (II) the phenol radical, the ortho-, meta-or para-cresol radical, 2,6-, 2,5-, 2,4-or 3,5-dimethylphenol radical, 2-methyl-6-phenylphenol radical, 2,6-diphenylphenol radical, 2,6-diethylphenol radical, 2-methyl-6-ethylphenol radical, 2,3,5-, 2,3,6-or 2,4,6-trimethylphenol radical, 3-methyl-6-tert-butylphenol radical, thymol radical, and 2-methyl-6-allylphenol radical, which may optionally be substituted at the oxygen atom.

Preferred examples of fluorine-containing radicals are the trifluoropropyl, nonafluorohexyl, and heptadecafluorooctyl radical.

Y is preferably a connecting organic unit having 1 to 24 carbon atoms between preferably two to twelve siloxanyl units. Y is preferably divalent, trivalent or tetravalent, especially divalent.

Preferred bridging aromatic radicals Y are those of the formulas (IIIa), (IIIb), and (IIIc)

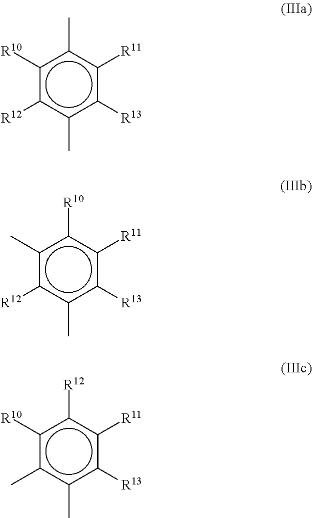

where the radicals R¹⁰, R¹¹, R¹², and R¹³ may be a hydrogen radical or an optionally substituted hydrocarbon radical or a group of the formula OR¹⁴, where R¹⁴ is a hydrocarbon radical. In formula (IIIa), neighboring radicals, for example R¹⁰ and R¹² or R¹¹ and R¹³, may be coupled to one another to form cyclic radicals, thus giving rise to fused ring systems.

Typical examples of such bridging aromatic radicals are the p-, m-or o-phenylene radical, the 2-methyl-1,4-phenylene radical, and the 2-methoxy-1,4-phenylene radical, with particular preference given to the p-phenylene radical.

It is optionally also possible for a plurality of such radicals to be coupled to one another such that, for example, two or more units of the formula (IIIa) are coupled to one another and this oligomeric bridging structural element is present through bonding of the corresponding carbon atoms of the terminal aromatic rings to silicon atoms. The aromatic units may be directly attached to each other or they may be coupled to one another by a bridging group such as an alkanediyl unit, for example the methylene group, 1,2-ethanediyl group, 1,1-ethanediyl group, 2,2-dimethylpropyl group or a sulfone group.

Further examples of aromatic bridging units are those in which two optionally substituted phenol rings, which are bridged via an alkanediyl or other unit. Typical representatives are 2,2-bis (4-hydroxyphenyl) propane radicals substituted at the phenolic oxygen (substituted bisphenol A radicals), 2,2-bis (4-hydroxyphenyl) methane radicals (substituted bisphenol F radicals), bis (4-hydroxyphenyl) sulfone radicals (bisphenol S radicals), where the phenolic oxygen atoms are typically substituted with radicals of the —(C₃H₆)— type, where the —(C₃H₆)— radicals are SiC-bonded to silicon atoms, thereby forming the bridge.

Preferred radicals Y not bridged by an aromatic unit are alkanediyl, alkenediyl, and alkynediyl radicals, which may optionally contain heteroatoms and which may contain aromatic groups as substituents, but these do not assume the function of bridging in these radicals or contribute thereto.

Typical examples are the methylene radical, the methine radical, tetravalent carbon, the 1,1-ethanediyl and the 1,2-ethanediyl group, the 1,4-butanediyl and the 1,3-butanediyl group, the 1,5-pentanediyl, 1,6-hexanediyl, 1,7-heptanediyl, 1,8-octanediyl, 1,9-nonanediyl, 1,10-decanediyl, 1,11-undecanediyl, and 1,12-dodecanediyl groups, the 1,2-diphenylethanediyl group, the 1,2-phenylethanediol group, and the 1,2-cyclohexylethanediyl group. Where a linear bridging unit has more than one carbon atom and the substitution pattern permits this, each of these groups may also act as a bridge through any other connectivity, i.e. the use of different chain atoms, other than that resulting from alpha, omega connectivity, i.e. bridging by the respective first and last atoms of a linear unit. Typical examples include moreover not just the linear representatives of the mentioned bridging hydrocarbons, but also the isomers thereof, which can in turn act as a bridge through bonding of different carbon atoms of the hydrocarbon structure to silicon atoms.

Examples of particularly preferred radicals from the group of non-aromatic heteroatom-free hydrocarbon radicals are —CH₂CH₂—, —CH(CH₃)—, —CH═CH—, —C(═CH₂)—, and —C≡C—.

Examples of typical fluorine-substituted bridging radicals Y are the —C(CF₃)₂— radical, the —C(H)F—C(H)F— radical, and the —C(F₂)—C(F₂)— radical.

Examples of typical heteroatom-containing bridging radicals are for example the ethyleneoxypropylene radical and the ethyleneoxybutylene radical. Also typical examples are double-sidedly —(CH₂)ₙ— or —CH₂—CH(R¹⁵)—C(═O)O-terminated radicals, where n is typically 3 to 8 and R¹⁵ is a hydrogen atom or a methyl group and glycol radicals or phenylene ether radicals attached to the silicon atoms via this terminal group.

All lists are by way of example only and not to be understood as limiting.

The organopolysiloxane compounds of the formula (I) may vary in viscosity over a wide range depending on the average number per molecule of the structural units that form them, or else they may be solids.

Liquid organopolysiloxane compounds of the formula (I) in the uncrosslinked state have viscosities at 25° C. of preferably from 20 to 8 000 000 mPa·s, more preferably from 20 to 5 000 000 mPa·s, especially from 20 to 3 000 000 mPa·s.

Solid organopolysiloxane compounds of the formula (I) in the uncrosslinked state have glass transition temperatures preferably in the range of from 25° C. to 250° C., more preferably from 30° C. to 230° C., especially from 30° C. to 200° C. Organopolysiloxanes that have bridging phenylene units and an overall aromatic proportion of at least 20 mol %, based on all SiC-bonded substituents as 100 mol %, have been found to be particularly suitable. Phenylene units are understood as meaning not just monomeric, but also oligomeric and substituted or unsubstituted phenylene units, as described in the examples illustrating the nature of the bridging substituents of this type.

The organopolysiloxane compounds of the formula (I) may be prepared by any desired method. A preferred method for preparing these compounds is the hydrolysis and cocondensation of compounds of the general formula (IV)

X₃-aRaSi—Y(SiRₐX₃₋ₐ)_{b} (IV)

with compounds of the formula (V)

R¹⁶ₕSiX₄₋ₕ (V),

where X is a hydrolyzable group,
H is an integer from 0 to 3,
where R¹⁶ is a radical R¹ when h=1, a radical R² when h=2, and a radical R³ when h=3
and R, Y, a, and b are as already defined above.

The compounds (IV) are obtained according to prior art methods, where the reaction types to be employed depend strongly on the composition of the respective compound (IV). Compounds (IV) are typically obtained by hydrosilylation, for example from olefinically unsaturated organic precursors, for example acetylene and diallyl or divinyl compounds and Si—H functional silicone building blocks.

Grignard reactions from halogenated organic precursors and subsequent reaction with halogenated or alkoxylated organosilanes are also conceivable methods here. It is also optionally possible to employ metal halide exchange reactions of halogenated organic precursors with alkyl compounds of the alkali metals, such as butyllithium, and known subsequent reactions for coupling with silicone building blocks. Such methods are known to those skilled in the art and are easily accessible and comprehensible from the available literature. Since these methods are not a subject matter of the invention, all that is provided at this point is reference to the documented and searchable prior art.

The relative ratios in which the compounds of the formula (IV) are cocondensed with the compounds of the formula (V) are determined by the values of the indices c, d, e, f, and g in formula (I).

Preferably, X is a halogen, acid or alkoxy group, more preferably a chlorine, acetate, formate, methoxy or ethoxy group.

The organosiloxanes obtained in this way may optionally be modified by further reactions, for example, the equilibration can be further altered and modified such that it is possible, through the use of known prior art methods, to produce virtually any desired branched siloxane oligomers and polymers and silicone resins, which are all understood in the context of the present invention as coming under the term organopolysiloxanes.

Preferably, the cohydrolysis is carried out such that a mixture of the compounds (IV) and (V) is metered into water or dilute acid while cooling. In the case of gaseous acids such as HCl, metered addition into a concentrated aqueous HCl solution is also useful if the released acid is to be recovered as a gas. The hydrolysis is varyingly exothermic, depending on the nature of group X, so cooling is necessary both in the interest of safe execution of the reactions and, where necessary, to avoid side reactions in the corresponding steps of the synthesis. However, in order for the reactions to proceed to completion it may be advantageous and necessary to employ elevated temperatures.

The reaction times in the case of chlorosilanes are usually very short, consequently the time needed to perform the process in batch operation depends primarily on the cooling capacity. Alternatively, the cohydrolysis of (IV) and (V) can also be carried out continuously, for which both loop reactors and also column reactors and tubular reactors are suitable.

For the depletion of residual acid, thorough washing with water, clean phase separation, and purification of the hydrolysis product under reduced pressure is advantageous.

The process can be carried out at standard pressure. However, higher or lower pressure is also practical, depending on the objective.

By using groups of the formula (R₃³SiO_{1/2})_{f} it is possible during the synthesis both to control the molecular weight and to reduce the alkoxy and silanol groups. The latter form during synthesis when this is carried out in a hydrolytic process, which is the preferred embodiment. When a chlorosilane precursor is used to produce the groups of the formula (R₃³SiO_{1/2})_{f}, symmetric disiloxanes are also formed therefrom in the course of the synthesis, but under the conditions of the acidic hydrolysis they can undergo renewed cleavage and accordingly remain available as terminating groups for reactions with silanol groups forming in the organopolysiloxane after hydrolysis of the chlorosilane starting materials. This permits the reduction of the silanol groups. Since alkoxy groups, in particular those having small alkyl radicals, likewise form silanol groups under the conditions of acidic hydrolysis, with short-chain alcohols being cleaved off, the alkoxy groups are reduced too by the concomitant use of the terminating building blocks. These can also be used in excess here, since any remaining disiloxanes can usually be distilled off at the end of the synthesis, particularly when they are substituted exclusively or predominantly with short-chain alkyl radicals, especially methyl radicals.

It is also possible to add the chlorosilanes or disiloxanes forming these terminal groups separately in a final step of the synthesis and to selectively bring about reduction of the silanol groups through acidic hydrolysis conditions. It is advantageous here always to use an excess of terminating chlorosilanes and to remove the resulting disiloxanes by distillation. Vinyldimethylchlorosilane, dimethylchlorosilane or trimethylchlorosilane can be used particularly advantageously for this purpose, since the resulting disiloxanes are particularly easily separable by distillation. Alternatively, it is also possible to use the disiloxanes straight away and to opt for hydrolytic conditions, in which case the addition of a sufficient amount of catalytically active acid, preferably hydrochloric acid, is necessary. The amount of hydrochloric acid used in this case is typically between 50 and 1000 ppm based on the amount of siloxane in the reaction mixture.

Residual silanol contents of less than 1 percent by weight are achieved. Since the exhaustive elimination of the silanol contents to the technically possible minimum is not a subject matter of the invention, this step was not further optimized.

The metal-clad laminates preferably contain formulations that contain organopolysiloxane compounds of the formula (I) and further constituents.

The organopolysiloxane compounds of the formula (I) are chemically curable, i.e. they can be cured by a chemical reaction to form a crosslinked insoluble network. Curing takes place via the olefinically unsaturated groups described hereinabove. Typically, either a free-radical polymerization reaction is employed for curing or—if a silicon-bonded hydrogen is also present as a radical in addition to the olefinically or ethylenically unsaturated functional groups-curing by hydrosilylation.

The organopolysiloxane compounds of the formula (I) all have aliphatically unsaturated functional groups via which they can be chemically crosslinked. Possible chemical crosslinking reactions here include the known reactions of the prior art, especially free-radical crosslinking, which can be initiated both by using suitable radiation sources such as UV light and also by unstable chemical compounds that break down to radicals and by addition crosslinking, for example by hydrosilylation of the olefinically unsaturated group with a Si—H function in the presence of a suitable hydrosilylation catalyst that is a further constituent of the formulations.

In order to achieve sufficient curing, a sufficient amount of functional groups have to be present. Per molecule of the organopolysiloxane compounds of the formula (I), an average of at least 1.0 functional groups must be present in order to achieve sufficient curing, preferably an average of at least 1.1, and especially an average of at least 1.2 functional groups per molecule of the organopolysiloxane compounds of the formula (I). The functional groups here may be different, such that, for example, one portion of the functional groups is a Si—H group and another portion of the functional groups is an olefinically unsaturated group that is curable by free radicals or hydrosilylatable. Further combinations of complementary functional groups are also conceivable, where complementary means that the selected combinations of functional groups are able to react with one another. If only one type of functional group is present, for example solely olefinically or acetylenically unsaturated functional groups that are curable by free radicals, the corresponding number of these functional groups needs to be present. For the purposes of copolymerization to form a homogeneous matrix, it should be ensured that the chosen olefinic and acetylene groups have adequate copolymerizability. Combining olefinic groups that cannot be copolymerized with one another is also possible, provided the resulting matrix of two or optionally more individual polymers remains mutually compatible and does not form separate phases that separate from one another into distinguishable domains.

As further constituents of the formulations, a suitable initiator may therefore be present to start the free-radical polymerization. Examples of suitable initiators here include in particular examples from the field of organic peroxides, such as di-tert-butyl peroxide, dilauryl peroxide, dibenzoyl peroxide, dicumyl peroxide, cumyl peroxyneodecanoate, tert-butyl peroxyneodecanoate, tert-amyl peroxypivalate, tert-butyl peroxypivalate, tert-butyl peroxyisobutyrate, tert-butyl peroxy-3,5,5-trimethylhexanoate, tert-butylcumyl peroxide, tert-butyl peroxyacetate, tert-butyl peroxybenzoate, 1,1-di-tert-butylperoxycyclohexane, 2,2-di (tert-butylperoxy) butane, bis (4-tert-butylcyclohexyl) peroxydicarbonate, hexadecyl peroxydicarbonate, tetradecyl peroxydicarbonate, dibenzyl peroxydicarbonate, diisopropylbenzene dihydroperoxide, [1,3-phenylenebis (1-methylethylidene)] bis [tert-butyl] peroxide, 2,5-dimethyl-2,5-di-(tert-butylperoxy) hexane, diacetyl peroxydicarbonate, acetylacetone peroxide, acetylcyclohexanesulfonyl peroxide, tert-amyl hydroperoxide, tert-amyl peroxy-2-ethylhexanoate, tert-amyl peroxy-2-ethylhexylcarbonate, tert-amyl peroxyisopropyl carbonate, tert-amyl peroxyneodecanoate, tert-amyl peroxy-3,5,5-trimethylhexanoate, tert-butyl monoperoxymaleate, this list being only illustrative and not limiting. It is optionally also possible to employ mixtures of different initiators for free-radical reactions. The suitability of an initiator or initiator mixture for free-radical reactions depends on its breakdown kinetics and the requirement conditions to be met. Taking sufficient account of these boundary conditions will allow a person skilled in the art to choose a suitable initiator.

In the case of organopolysiloxane compounds of the formula (I) containing not just olefinically and acetylenically unsaturated groups but also silicon-bonded hydrogen, there is the option of curing by means of a hydrosilylation reaction. Suitable catalysts for promoting the hydrosilylation reaction may be present as further constituents of the formulations.

Examples of such catalysts are compounds or complexes of the group of noble metals comprising platinum, ruthenium, iridium, rhodium, and palladium, preferably metal catalysts from the group of the platinum metals or compounds and complexes from the group of platinum group metals. Examples of such catalysts are metallic and finely divided platinum, which may be supported on supports such as silicon dioxide, aluminum oxide or activated carbon, compounds or complexes of platinum such as platinum halides, for example PtCl₄, H₂PtCl₆·6H₂O, Na₂PtCl₄·4H₂O, platinum olefin complexes, platinum alcohol complexes, platinum alkoxide complexes, platinum ether complexes, platinum aldehyde complexes, platinum ketone complexes, including reaction products of H₂PtCl₄·6H₂O and cyclohexanone, platinum vinylsiloxane complexes such as platinum 1,3-divinyl-1,1,3,3-tetramethyldisiloxane complexes, with or without a content of detectable inorganically bonded halogen, bis (gamma-picoline) platinum chloride, trimethylenedipyridineplatinum chloride, dicyclopentadieneplatinum dichloride, dimethylsulfoxyethenylplatinum (II) dichloride, cyclooctadieneplatinum dichloride, norbornadieneplatinum dichloride, gamma-picolineplatinum dichloride, cyclopentadieneplatinum dichloride, and also reaction products of platinum tetrachloride with olefin and primary or secondary amine or primary and secondary amine such as the reaction product of platinum tetrachloride dissolved in 1-octene with sec-butylamine or ammonium platinum complexes. In a further embodiment, complexes of iridium with cyclooctadienes, for example μ-dichlorobis (cyclooctadiene) diiridium (I), are used.

This list is only illustrative and is not limiting. The development of hydrosilylation catalysts is a dynamic field of research that is constantly yielding new active species that may of course also be employed here.

The hydrosilylation catalyst is preferably selected from compounds or complexes of platinum, preferably platinum chlorides and platinum complexes, especially platinum olefin complexes, and more preferably platinum divinyltetramethyldisiloxane complexes.

In the curing process, the hydrosilylation catalyst is employed in amounts of 2 to 250 ppm by weight, preferably in amounts of 3 to 150 ppm, especially in amounts of 3 to 50 ppm.

The organopolysiloxane compounds of the formula (I) are particularly well suited for use as binders for producing metal-clad electrolaminates, for example those used for producing printed circuit boards in electronic devices, especially for high-frequency uses.

These metal-clad electrolaminates may contain reinforcing materials, but they do not have to. This means they may for example contain reinforcing fabrics such as fiber fabrics or nonwovens or they may be free of them. If a reinforcing material is present, this is preferably arranged in layers. A reinforcing layer may here be made up of a multiplicity of different fibers.

Such reinforcing layers help to control shrinkage and impart enhanced mechanical strength.

If a reinforcing layer is included, the fibers forming this layer may be selected from a variety of different options. A non-limiting list of examples of such fibers includes glass fibers, such as E-glass fibers, S-glass fibers, and D-glass fibers, silica fibers, polymer fibers, such as polyetherimide fibers, polysulfone fibers, polyetherketone fibers, polyester fibers, polycarbonate fibers, aromatic polyamide fibers or liquid crystalline fibers. The fibers may have a diameter of 10 nm to 10 μm. The reinforcing layer has a thickness of not more than 200 μm, preferably not more than 150 μm.

A preferred form of use is the use of the organopolysiloxane compounds of the formula (I) as binder or cobinder together with organic binders for producing metal-clad laminates from glass fiber composites for the further production of printed circuit boards. The preferred metal is copper.

The organopolysiloxane compounds of the formula (I) may be used as the sole binder. As further constituents of the formulations, organic binders may also be present. Organic binders used are for example organic monomers, oligomers, and polymers.

Organic monomers, oligomers, and polymers typically used for this purpose include polyphenylene ethers, bismaleimides, bismaleimide triazine copolymers, hydrocarbon resins, both aliphatic, such as polybutadiene, and aromatic, such as polystyrene, as well as hybrid systems having both aliphatic and aromatic character, for example styrene-polyolefin copolymers, there being in turn no restriction in principle on the form of the copolymers, epoxy resins, cyanate ester resins and optionally others, it being understood that the selection is illustrative and not limiting.

Preferred organic monomers, oligomers, and polymers are oligomeric and polymeric polyphenylene ethers, monomeric, oligomeric, and polymeric bismaleimides, oligomeric and polymeric hydrocarbon resins, and bismaleimide-triazine copolymers.

Said organic monomers, oligomers, and polymers may optionally be mixed with one another.

Where the organic components are additionally used, the proportion of organic monomers, oligomers, and polymers in the formulations comprising organopolysiloxane compounds of the formula (I) is between 10 and 90% based on the mixture of the organopolysiloxane compounds of the formula (I) and the organic monomers, oligomers, and polymers as 100%, preferably 20-90%, especially 30-80%.

In addition, both the organopolysiloxane compounds of the formula (I) and mixtures thereof with organic monomers, oligomers or polymers may be dissolved in further organic monomers optionally having olefinically or acetylenically unsaturated groups as reactive diluents, for example styrene, alpha-methylstyrene, para-methylstyrene and vinylstyrene, chlorostyrene, and bromostyrene.

The formulations may also comprise as further constituents typical non-reactive solvents for dissolving the organopolysiloxane compounds of the formula (I) and optionally mixtures thereof with organic monomers, oligomers, and polymers, for example aliphatic or aromatic solvents, such as aliphatic mixtures having defined boiling ranges, toluene, xylene, ethylbenzene or mixtures of said aromatics, ketones, such as acetone, methyl ethyl ketone, cyclohexanone, carboxylic esters, such as ethyl acetate, methyl acetate, ethyl formate, methyl formate, methyl propionate, ethyl propionate, wherein good solubility, especially of the mixtures of organopolysiloxane compounds of the formula (I) with organic monomers, oligomers, and polymers, is most likely achieved in aromatic solvents such as toluene, xylene, ethylbenzene, and mixtures thereof.

Where the organopolysiloxane compounds of the formula (I) are used in combination with an organic oligomer or polymer or mixtures thereof, it is essential that organopolysiloxane compounds of the formula (I) are used that are compatible with the chosen organic components and do not lead to phase separations. In such cases, more phenyl-rich organopolysiloxane compounds of the formula (I) are generally to be used, since phenyl groups increase compatibility with the organic components. Particularly with organic polymers having a greater aromatic component, such as polyphenylene ethers or aromatic hydrocarbon resins, use should be made of organopolysiloxane compounds of the formula (I) having a greater aromatic component, wherein both the bridging aromatic groups and the aromatic substituents terminally attached to silyl units contribute to adjusting the compatibility. The exact amount of aromatic groups necessary to adjust the compatibility of the organopolysiloxane compounds of the formula (I) with a particular choice of organic binders must be determined according to the choice of organic binders. It is also possible to mix a plurality of organic polymers, optionally selected from different polymer classes, and to use this in the binder formulation. It is also possible to combine a plurality of organopolysiloxane compounds of the formula (I) with one another in the binder formulation. In other words, it is in accordance with the invention for just a sole organopolysiloxane compound of the formula (I) to be used as binder or for a plurality of organopolysiloxane compounds of the formula (I) to be combined with one another into a binder formulation. It is likewise in accordance with the invention for just one organopolysiloxane compound of the formula (I) to be combined with one or more organic polymers into a binder formulation. It is also in accordance with the invention for a plurality of organopolysiloxane compounds of the formula (I) to be combined with one or more different organic polymers into a binder formulation.

The compatibility of one or more organopolysiloxane compounds of the formula (I) with one or more organic oligomers or polymers is easily established by mixing a mixture of the organic binder(s) with the organopolysiloxane compound(s) of the formula (I), advantageously in a solvent in which all selected components dissolve, and then removing the solvent by prior art methods, for example by distillation or spray drying, and assessing the residue obtained visually or with the aid of microscopic or optionally electron microscopic methods. Compatible mixtures can be recognized in that there are no silicone domains separate from the organic constituents and recognizable as a discrete phase.

As further constituents, the formulations may comprise further formulation components, such as additives, which may optionally also include silanes, for example antifoam and deaeration agents, wetting and dispersing agents, leveling agents, compatibilizers, adhesion promoters, curing initiators, catalysts, stabilizers, fillers including pigments, dyes, inhibitors, flame-retardant additives, and crosslinking aids. In addition to tests of compatibility in the sense of suitable miscibility behavior, tests of compatibility with regard to reactivity may also be required in order both to prevent premature gelling and to ensure that sufficiently rapid polymerization/copolymerization of all components with one another is achieved during curing, as well as tests for sufficient wetting and optionally other properties. This must where necessary be observed and taken into account in the creation of the formulation.

Examples of usable fillers are ceramic fillers such as silicas, for example precipitated silicas or fumed silicas, which may be either hydrophilic or hydrophobic, preferably hydrophobic, and which may in addition be functionally and optionally reactively furnished on their surface with organic groups, quartz, which may optionally be surface-treated or surface-functionalized such that it can optionally bear reactive functional groups on its surface, aluminum oxides, aluminum hydroxides, calcium carbonate, talc, mica, clay, kaolin, magnesium sulfate, carbon black, titanium dioxide, zinc oxides, antimony trioxide, barium titanate, strontium titanate, corundum, wollastonite, zirconium tungstate, ceramic hollow spheres, aluminum nitride, silicon carbide, beryllium oxide, magnesium oxide, magnesium hydroxide, solid glass spheres, hollow glass spheres, and boron nitride. As further fillers, it is possible to use core-shell particles made of various materials, for example silicone resin spheres surface-coated with silica or polymer-coated elastomer particles, wherein the elastomer particles may optionally also be silicone elastomers, a typical example of a surface coating of such an elastomer particle being a polymethyl methacrylate shell. The ceramic fillers preferably have particle sizes expressed as D90 values of from 0.1 μm to 10 μm. Fillers are preferably present in amounts of from 0.1 to 60 percent by weight, preferably from 0.5 to 60 percent by weight, especially from 1 to 60 percent by weight, based on the total binder formulation consisting of binder(s), reactive monomers, additives, and fillers as 100%. This means that the amount of any non-reactive solvent used is not counted.

In the case of fillers, those that are thermally conductive are worthy of special mention. These are aluminum nitride, boron nitride, silicon carbide, diamond, graphite, beryllium oxide, zinc oxide, zirconium silicate, magnesium oxide, silicon oxide, and aluminum oxide.

The binder formulations may in principle contain flame-retardant additives in an amount of usually 5 to 25 percent by weight. However, it is a special feature of the organopolysiloxane compounds of the formula (I) that they reduce the need for flame-retardant additives, since the organopolysiloxane compounds of the formula (I) themselves already exhibit flame-retardant properties. Polysilsesquioxanes and siloxanes are known for exhibiting flame-retardant properties and their use as flame-retardant additives is prior art. A particular advantage of the present invention is therefore that it is possible here to couple the function of the binder with the function of flame retardancy. Depending on the amount of organopolysiloxane compounds of the formula (I) used, it is therefore possible to reduce the amount of flame-retardant additives. When the amount used is at least 20 percent by weight based on the total mixture of all employed binders and reactive organic monomers, the amount of flame-retardant additives still present is preferably only 0 to 10 percent by weight, more preferably 0 to 8 percent by weight, especially 0 to 5 percent by weight, in other words use of the organopolysiloxane compounds of the formula (I) make it possible, depending on the selected organopolysiloxane and the amount used, to dispense with the use of a flame-retardant additive.

Typical examples of flame-retardant additives are hydrates of the metals Al, Mg, Ca, Fe, Zn, Ba, Cu or Ni and borates of Ba and Zn. The flame-retardant additives may be surface-treated, as a result of which they may optionally have reactive groups on their surface. The flame-retardant additives may also be halogenated organic flame-retardant additives, such as hexachloroendomethylenetetrahydrophthalic acid, tetrabromophthalic acid or dibromoneopentyl glycol. Examples of other flame-retardant additives are melamine cyanurate and phosphorus-containing components such as phosphinates, diphosphinates, phosphazenes, vinyl phosphazenes, phosphonates, phosphaphenanthrene oxides, and fine-grained melamine polyphosphates.

Further examples of bromine-containing flame-retardant additives are bis (pentabromophenyl) ethane, ethylene bis (tetrabromo) phthalimide, tetradecabromodiphenoxybenzene, decabromodiphenyl oxide or brominated polysilsesquioxanes. Some flame-retardant additives synergistically reinforce each other's effect. This is the case, for example, for the combination of halogenated flame retardants with antimony trioxide.

The formulations may also include as further constituents antioxidants, stabilizers against degradation due to weathering, lubricants, plasticizers, colorants, phosphorescent agents or other agents for the purposes of marking and traceability, and antistats.

Crosslinking aids employed are in particular polyunsaturated monomers and oligomers that are curable by free radicals or hydrosilylatable, as illustrated in the non-limiting examples that follow. Examples include doubly olefinically unsaturated components, for example symmetrically olefinically unsaturated disubstituted disiloxanes, such as 1,1,3,3-tetramethyl-1,3-divinyldisiloxane, 1,1,3,3-tetramethyl-1,3-dipropylmethacryloyldisiloxane, doubly olefinically unsaturated disubstituted organic monomers, for example ones that are diallyl-, divinyl-, diacryloyl-or dimethacryloyl-substituted, or oligomers, for example conjugated and unconjugated dienes such as 1,9-decadiene and 1,3-butadiene. These also include triply olefinically unsaturated monomers or oligomers such as 1,2,4-trivinylcyclohexane, triallyl cyanurates or triallyl isocyanurates, and tri (meth) acrylates, for example trimethylolpropane trimethacrylate. These also include quadruply unsaturated substituted monomers and oligomers, for example 2,4,6,8-tetramethyl-2,4,6,8-tetravinylcyclotetrasiloxane, 2,4,6,8-tetraphenyl-2,4,6,8-tetravinylcyclotetrasiloxane, 2,2-bis [[(2-methyl-1-oxoallyl) oxy] methyl]-1,3-propanediyl bismethacrylate (pentaerythritol tetramethacrylate), tetraallyl orthosilicate, tetraallyl-cis, cis, cis, cis-1,2,3,4-cyclopentanetetracarboxylate, tetraallylsilane, and glyoxal bis (diallylacetal).

Since, in addition to free-radical curing, curing by hydrosilylation is also conceivable, it is also possible for multiply Si—H functional components to act as crosslinkers, for example 1,1,3,3-tetramethyl-1,3-disiloxane, 2,4,6,8-tetramethylcyclotetrasiloxane, 1,4-bis (dimethylsilyl) benzene or oligo- and polyorganosiloxanes multiply Si—H functional in the chain and/or terminally.

Useful catalysts/initiators for the free-radical curing of binder formulations of organopolysiloxane compounds of the formula (I) and organic monomers, oligomers, and polymers are the same as those already mentioned hereinabove, i.e. peroxides in particular. In addition, other free-radical starters suitable for initiating the free-radical curing both of the organopolysiloxane compounds of the formula (I) on their own and of the binder formulations described are azo components, such as α,α′azobis (isobutyronitrile), redox initiators, for example combinations of peroxides such as hydrogen peroxide and iron salts, or azides such as acetyl azide.

The organopolysiloxane compounds of the formula (I) and the formulations comprising them may be employed for use according to the invention both as solvent-free and solvent-containing formulations. They are generally used in the form of a solvent-containing formulation so as to facilitate the homogeneous mutual dispersion of all components of the formulation and the wetting and impregnation of any reinforcing layer used. A reinforcing layer is generally used. It is preferably a glass fiber fabric. Saturation of the reinforcing layer can be achieved through an impregnating application of the formulation, there being various technical solutions available for this purpose, optionally including continuous processes, and the selection thereof for the production of the metal-clad laminates of the invention is in no way limited. Non-limiting examples of application techniques are dipping, optionally of webs of the reinforcing material via roller systems in continuous processes, spraying, flooding, knife coating, etc. It is an advantage of the present invention that all available technologies may be employed without limitation and modification and that no special new method is required for use of the organopolysiloxane compounds of the formula (I). In this respect, the present invention is entirely within the existing prior art in the production of metal-clad laminates. What is novel is the use of the organopolysiloxane compounds of the formula (I) for producing the metal-clad laminates concerned, which is up to now unknown.

Impregnation is followed by a drying step in which any solvent used is removed. Prior art methods are also used for the drying process. These include in particular thermally-induced evaporation with or without vacuum. Appropriate adjustment of the reactivity and of the tackiness of the binder mixture used affords, after this step, composite materials that are storable under suitable conditions, for example refrigeration, and may be processed further at a later time.

In a final step of the process the binder formulation undergoes polymerization, again according to prior art methods Optionally included initiators for the free-radical polymerization are heated above their decomposition temperature, such that they break down to form free radicals and initiate the free-radical polymerization of the binder formulation. Radiation-curing methods can in principle also be employed. If curing by hydrosilylation is used instead of free-radical polymerization, a temperature needs to be used in this step that is able to deactivate the inhibitor employed for the hydrosilylation catalyst used and to unleash the catalytic activity of the hydrosilylation catalyst.

This step is usually carried out at an elevated temperature, of preferably from 100 to 390° C., more preferably from 100 to 250° C., especially from 130 to 200° C., this temperature being operative for a time of preferably from 5 to 180 min, more preferably 5 to 150 min, especially 10 to 120 min. In addition, it is usual to apply increased pressure in this step. Usual pressures are in the range from 1 to 10 MPa, more preferably from 1 to 5 MPa, especially from 1 to 3 MPa.

The composite material undergoes lamination with a conductive metal layer in this second step by applying a layer of at least one selected metal on one or both sides of the composite material composed of reinforcing layer and binder formulation, before curing takes place. In other words, between the first step consisting of impregnation and drying and the second step comprising the chemical curing of the binder formulation, the composite from the first step undergoes lamination with at least one type of conductive metal.

Useful conductive metals include at least one of the following: copper, stainless steel, gold, aluminum, silver, zinc, tin, lead, and transition metals. The thickness of the conductive layer and the shape, size or surface texture thereof are not in principle limited. The conductive metal layer preferably has a thickness of from 3 to 300 μm, more preferably from 3 to 250 μm, especially from 3 to 200 μm. The thickness of the two layers of at least one type of conductive metal, where two layers are used, may vary and does not need to be the same. It is particularly preferable that the conductive metal is copper and, when two conductive layers of conductive metal are used, that both layers are copper. The conductive metal is preferably used in the form of a foil of the metal concerned. The arithmetical mean roughness Ra of the metal foil used is preferably not more than 2 μm, more preferably not more than 1 μm, especially not more than 0.7 μm. The lower the surface roughness, the better the suitability of the respective foil for use in high-frequency applications, which are the preferred objective of the present invention. To improve adhesion between the conductive metal layer and the composite of binder formulation and reinforcing layer, various prior art methods may be employed, for example the use of an adhesion-mediating layer, deposition by electroplating of the metal layer on the composite of binder formulation and reinforcing layer, or gas-phase deposition. The layer of conductive metal may rest directly on the composite composed of binder formulation and reinforcing layer or be connected to it by an adhesion-mediating layer.

If no reinforcing layer is included, the creation of a layer of the binder formulation comprising the organopolysiloxane compounds of the formula (I) is preferably achieved by depositing a layer of binder formulation on a carrier, for example a separating film or separating plate, where a suitable material for the carrier is in principle any from which the dried or cured binder formulation is detachable again at a later time, for example polytetrafluoroethylene, polyester, and the like. Detachability and film-forming properties on the respective carrier material must be individually determined according to the binder composition. The statements made regarding the process remain equally applicable to this reinforcement-free variant.

The reinforced or unreinforced composite materials from the first step and the laminated composite materials from the second step can be used to create multilayer structures by stacking on top of one another a plurality of layers of the composite materials from the first step, for example alternately with the clad laminates from the second step, and then curing the up-to-now uncured composite materials from the first step in a process that corresponds essentially to the procedure for producing the metal-clad laminates. To create thicker layers, a plurality of layers of the reinforced or unreinforced composites from the first step can be stacked on top of one other in direct succession.

As well as for the production of metal-clad laminates, the organopolysiloxane compounds of the formula (I) may be used in corrosion-protective formulations, especially for the purposes of corrosion protection at high-temperatures.

In addition, the organopolysiloxane compounds of the formula (I) and formulations comprising them can also be used for corrosion protection of reinforcing steel in reinforced concrete. Corrosion-inhibiting effects in reinforced concrete are achieved both when the organopolysiloxane compounds of the formula (I) and formulations comprising them are introduced into the concrete mixture before they are shaped and cured, and when the organopolysiloxane compounds of the formula (I) or formulations comprising them are applied to the surface of the concrete after the concrete has cured.

In addition to the purpose of corrosion protection on metals, the organopolysiloxane compounds of the formula (I) may also be used for manipulating further properties of formulations comprising the organopolysiloxane compounds of the formula (I) or of solid articles or films obtained from formulations comprising the organopolysiloxane compounds of the formula (I), for example:
controlling electrical conductivity and electrical resistance,
controlling the flow properties of a formulation,
controlling the gloss of a wet or cured film or of an object,
increasing weathering resistance,
increasing chemical resistance,
increasing color stability,
reducing chalking tendency,
reducing or increasing the stick or slip friction of solid articles or films obtained from formulations comprising organopolysiloxane compounds of the formula (I),
stabilizing or destabilizing foam in the formulation comprising the formulation of the invention,
improving the adhesion to substrates of the formulation comprising organopolysiloxane compounds of the formula (I),
controlling filler behavior, pigment wetting behavior, and dispersion behavior,
controlling the rheological properties of the formulation comprising the organopolysiloxane compounds of the formula (I),
controlling the mechanical properties, for example flexibility, scratch resistance, elasticity, extensibility, bendability, tear behavior, rebound behavior, hardness, density, tear propagation resistance, compression set, behavior at different temperatures, expansion coefficient, abrasion resistance, and further properties such as the thermal conductivity, flammability, gas permeability, resistance to water vapor, hot air, chemicals, weathering, and radiation, and sterilizability of obtainable solid articles or films comprising the organopolysiloxane compounds of the formula (I) or formulations comprising them,
controlling electrical properties, for example dielectric loss factor, dielectric strength, dielectric constant, tracking resistance, arc resistance, surface resistance, specific dielectric strength,
flexibility, scratch resistance, elasticity, extensibility, bendability, tear behavior, rebound behavior, hardness, density, tear propagation resistance, compression set, behavior at different temperatures of solid articles or films obtainable from the formulation comprising the organopolysiloxane compounds of the formula (I).

Examples of applications in which the organopolysiloxane compounds of the formula (I) may be used to manipulate the properties described above are the production of coating compositions and impregnations and coatings and coverings obtainable therefrom on substrates such as metal, glass, wood, mineral substrates, synthetic and natural fibers for production of textiles, carpets, floor coverings or other goods producible from fibers, leather, plastics, such as films, and moldings. With appropriate selection of the formulation components, the organopolysiloxane compounds of the formula (I) may also be used in formulations as an additive for the purposes of defoaming, flow promotion, hydrophobization, hydrophilization, filler and pigment dispersion, filler and pigment wetting, substrate wetting, promoting surface smoothness, reducing stick or slip friction on the surface of the cured compound obtainable from the additized formulation. The organopolysiloxane compounds of the formula (I) may be incorporated in liquid form or in cured solid form into elastomer compounds. They may be used here for the purposes of reinforcing or improving other performance properties, such as controlling transparency, heat resistance, yellowing tendency or weathering resistance.

All of the above symbols in the above formulas are in each case defined independently of one another. In all of the formulas the silicon atom is tetravalent.

### EXAMPLES

The following examples serve to further elucidate the invention: They are to be understood as illustrative, but not limiting.

All percentages are percentages by weight. Unless otherwise stated, all manipulations are performed at room temperature of 23° C. and at standard pressure (1.013 bar).

Unless otherwise stated, all data for describing product properties pertain to room temperature of 23° C. and standard pressure (1.013 bar).

The apparatuses are commercially available laboratory apparatuses such as are commercially available from numerous apparatus manufacturers.
Ph is a phenyl radical=C₆H₅—.
Me is a methyl radical=CH₃—. Me₂ accordingly is two methyl radicals.
PPE is polyphenylene ether.
HCl is hydrogen chloride.

In the present text, substances are characterized by reporting data obtained by instrumental analysis. The underlying measurements are either performed according to publicly accessible standards or determined using specially developed methods. To ensure the clarity of the disclosed teaching, the methods used are specified hereinbelow.

In all examples the reported parts and percentages refer to weight, unless otherwise stated.

### Viscosity:

Unless otherwise stated, viscosities are determined by rotational viscometry in accordance with DIN EN ISO 3219. Unless otherwise stated, all viscosity data pertain to 25° C. and standard pressure of 1013 mbar.

### Refractive Index:

Unless otherwise stated, refractive indices are determined in the visible light wavelength range, at 589 nm at 25° C. and standard pressure of 1013 mbar in accordance with the standard DIN 51423.

### Transmittance:

Transmittance is determined by UV-Vis spectroscopy. A suitable instrument is for example the Analytik Jena Specord 200.

The employed measurement parameters are: range: 190-1100 nm, step width: 0.2 nm, integration time: 0.04 s, measurement mode: step mode.

The reference measurement (background) is performed first. A quartz plate mounted in a sample holder (dimensions of quartz plates: height×width approx. 6×7 cm, thickness approx. 2.3 mm), is placed in the sample beam and measured against air. This is followed by the sample measurement. A quartz plate mounted in the sample holder and containing the applied sample in a layer thickness of approx. 1 mm is placed in the sample beam and measured against air. Internal calculation versus the background spectrum gives the transmission spectrum of the sample.

### Molecular Compositions:

Molecular compositions are determined by nuclear magnetic resonance spectroscopy (for terminology see ASTM E 386: High-resolution nuclear magnetic resonance (NMR) spectroscopy: Terms and symbols), with measurement of the ¹H nucleus and ²⁹Si nucleus.

### Description of ¹H-NMR Measurement

Solvent: CDCl3, 99.8% D
Sample concentration: Approx. 50 mg/l ml CDCl3 in 5 mm NMR tubes

Measurement without addition of TMS, referencing of spectra to residual CHCI3 in CDCl3 at 7.24 ppm
Spectrometer: Bruker Avance I 500 or Bruker Avance HD 500
Probe: 5 mm BBO probe or SMART probe (Bruker)
Measurement parameters:
Pulprog=zg30
TD=64k
NS=64 or 128 (depending on probe sensitivity)
SW=20.6 ppm
AQ=3.17 s
D1=5 s
SFO1=500.13 MHZ
O1=6.175 ppm
Processing parameters:
SI=32k
WDW=EM
LB=0.3 Hz

Depending on the spectrometer model used, individual adjustments to the measurement parameters may be necessary.

### Description of ²⁹Si-NMR Measurement

Solvent: C6D6 99.8% D/CCI4 1:1 v/v with 1% by weight of Cr(acac)₃ as relaxation agent
Sample concentration: Approx. 2 g/1.5 ml solvent in 10 mm NMR tubes
Spectrometer: Bruker Avance 300
Probe: 10 mm 1H/13C/15N/29Si glass-free QNP probe (Bruker)
Measurement parameters:
Pulprog=zgig60
TD=64k
NS=1024 (depending on probe sensitivity)
SW=200 ppm
AQ=2.75 s
D1=4 s
SFO1=300.13 MHZ
O1=−50 ppm
Processing parameters:
SI=64k
WDW=EM
LB=0.3 Hz

Depending on the spectrometer model used, individual adjustments to the measurement parameters may be necessary.

### Molecular Weight Distributions:

Molecular weight distributions are determined as the weight-average Mw and the number-average Mn using the methods of gel-permeation chromatography (GPC) and size-exclusion chromatography (SEC) with a polystyrene standard and a refractive index detector (RI detector). Unless otherwise stated, THF is used as eluent and DIN 55672-1 is followed. Polydispersity is the ratio Mw/Mn.

### Determination of Dielectric Properties: Df, Dk

Dielectric properties are determined in accordance with IPC TM 650 2.5.5.13 using a Keysight/Agilent E8361A network analyzer by the split-cylinder resonator method at 10 GHz.

### Synthesis Example 1: Preparation of an Organopolysiloxane Compound of the Formula (I): Synthesis Following the Procedure of DE 102005040323, Example 1, Leads to the Result Described Therein

A mixture of 109 g of redistilled 1,2-bis (methyldichlorosilyl) ethane and 820 g of vinyldimethylchlorosilane is cooled to 10° C. While stirring and at the same time cooling, a total of 1.7 l of 5% HCl solution is added over approx. 80 minutes such that the temperature of the reaction mixture can be maintained at 10-20° C. The mixture is then stirred vigorously for 30 minutes, after which the phases are separated. The siloxane phase is washed with four 1 l portions of water, neutralized with 0.5 l of 5% NaHCO₃ solution, and washed again with 1 l of water. Volatile hydrolysis products (mainly divinyltetramethyldisiloxane) are removed under reduced pressure at up to 80° C. This affords 149.8 g of a clear liquid as a residue having a viscosity of 7.2 mm²/s (25° C.) and with an iodine value of 169.6, exactly one C═C double bond per 149.8 g. The ratio of terminal groups to branching units is 2.57. The product contains approx. 90% of the employed 1,2-bis (methyldichlorosilyl) ethane in hydrolyzed form.

### Synthesis Example 2: Preparation of a Silphenylene-Bridged Organopolysiloxane Compound of the Formula (I)

### Synthesis of the Silphenylene Precursor

1,4-Bis (dimethoxyphenylsilyl) benzene in accordance with the literature procedure of Xunjun Chen, Minghao Yi, Shufang Wu, Lewen Tan, Yixin Xu, Zhixing Guan, Jianfang Ge, and Guoqiang Yin: Synthesis of Silphenylene-Containing Siloxane Resins Exhibiting Strong Hydrophobicity and High Water Vapor Barriers, Coatings 2019, 9, 481; doi: 10.3390/coatings9080481 www.mdpi.com/journal/coatings

1,4-Bis (dimethoxyphenylsilyl) benzene is obtained by reacting trimethoxyphenylsilane with a Grignard reagent obtained from 1,4-dibromobenzene according to the cited literature “2.2. Synthesis of the 1,4-bis (dimethoxyphenylsilyl) benzene (BDMPD)”. The structure was confirmed by ¹H-NMR spectroscopy and comparison with the cited literature.

A mixture of 845.2 g (=4 mol) of phenyltrichlorosilane, 546.7 g (1.3 mol) of 1,4-bis (dimethoxyphenylsilyl) benzene, 198.7 g (0.8 mol) of 3-trimethoxysilylpropyl methacrylate, and 820 g of xylene is metered over a period of 4 hours into an initial charge of 2400 g of demineralized water. The initial charge is at the start of metering at room temperature of 23° C. The temperature rises as a result of the exothermic evolution of heat during the reaction. The metering is controlled such that the internal temperature in the reaction vessel at no time rises above 50° C. If necessary, the metering rate is reduced.

At the end of the metered addition, the mixture is stirred for 15 min. The stirrer is then switched off. The organic phase and the aqueous phase separate. The lower, aqueous, clear and colorless phase, which consists essentially of a concentrated aqueous hydrochloric acid solution, is run off.

To the organic phase remaining in the reaction vessel is added 1 I of demineralized water and the vessel contents are mixed by stirring. After 30 min the stirrer is switched off and the phases allowed to separate again. The aqueous phase settles as the lower phase and is run off. If the aqueous phase settles as the upper phase, the mixture is washed again for 30 min with an aqueous 10% sodium chloride solution instead of demineralized water or 100 g of sodium chloride added, after which the phase separation is again carried out. This process is repeated until the residual HCl content in the organic phase is below 20 ppm. The residual HCl content is determined by an acid-base titration in accordance with the prior art. As a rule, two washes with demineralized water or 10% aqueous NaCl solution are sufficient. Water is then removed by azeotroping at 110° C. with xylene as water entrainer until no more water is obtained.

The product obtained at this stage in the synthesis contains approx. 3% by weight of silanol groups, which interfere with the target application on account of their polarity. To reduce the silanol content, the following procedure is employed:
200 g of water is metered into the xylenic reaction mixture remaining after the above distillation. 265.1 g (2.2 mol) of vinyldimethylchlorosilane is then added slowly, adjusting the metering rate such that the reaction temperature (internal temperature in the reaction vessel) remains below a limit of 50° C. At the end of metering, the mixture is stirred for a further 60 min without either heating or cooling in order that the reaction of the silanol groups with the vinyldimethylchlorosilane or with the tetramethyldivinyldisiloxane formed therefrom proceeds to completion.

The aqueous phase is removed as described above and the mixture then washed with three one-liter portions of water as previously described above. If necessary, the phase separation can be improved by heating to a heating jacket temperature of 60° C. with the stirrer switched off. After washing, the HCl content in the xylenic solution is less than 20 ppm.

The amount of xylene is reduced by distillation under reduced pressure (20 mbar) at 110° C. until a solution of 80% resin in 20% xylene is obtained.

Methoxy groups are no longer detectable by 1H NMR in the product obtained. This means that the methacrylate-functional trimethoxysilane has been fully incorporated by condensation; the resulting methanol was removed during workup. The further treatment reduces the proportion of silanol groups to approx. 0.9 percent by weight (determined by 1H NMR).

The following molecular weights were determined by SEC (eluent toluene):
Mw=7347 g/mol, Mn=2903 g/mol, polydispersity PD=2.53.

According to ²⁹Si NMR, the molar composition of the silicon-containing fraction of the formulation is:
Me₂Si(Vi)O_{1/2}:11.54%
H₂C═C(CH₃)C(═O)—O—(CH₂)₃—SiO_{3/2}:11.98%
O_{2/2}(Ph)Si—C₆H₄—Si(Ph)O_{2/2}:19.23%
PhSiO_{3/2}:57.25%

The silanol groups are attached to the PhSiO_{3/2} units.

### Synthesis Example 3: Preparation of an Organopolysiloxane Compound of the Formula (I) Having Phenylene Bridges

The synthesis according to synthesis example 2 is repeated, but using the starting materials in the following amounts instead of those in synthesis example 2:
Phenyltrichlorosilane: 281.7 g (=1.3 mol)
1,4-Bis (dimethoxyphenylsilyl) benzene: 1202.7 g (2.9 mol)

The rest of the procedure corresponds to that of synthesis example 3. The following result is obtained:
Methoxy groups are not detectable in the NMR. The residual silanol content is 0.8 percent by weight.
SEC: Mw=8347 g/mol, Mn=3953 g/mol, polydispersity PD=2.11.

According to ²⁹Si NMR, the molar composition of the silicon-containing fraction of the formulation is:
MezSi(Vi)O_{1/2}:10.93%
H₂C═C(CH₃)C(═O)—O—(CH₂)₃—SiO_{3/2}:10.89%
O_{2/2}(Ph)Si—C₆H₄—Si(Ph)O_{2/2}:49.96%
PhSiO_{3/2}:28.22%

### Synthesis Example 4: Preparation of an Organopolysiloxane Compound of the Formula (I) Having Alkylene Bridges

The synthesis according to synthesis example 2 is repeated, but using the starting materials in the following amounts instead of those in synthesis example 2:
Phenyltrichlorosilane: 422.6 g (=2 mol)
1,2-Bis (dichloromethylsilyl) ethane: 341.35 g (1.35 mol)
Vinyldimethylchlorosilane: 403.7 g (3.35 mol)
No 1,4-bis (dimethoxyphenylsilyl) benzene is used.

In this synthesis, 271.2 g (2.25 mol) of vinyldimethylchlorosilane is added directly to the chlorosilane mixture metered into the initial charge of water in the first step. The remaining 132.6 g (1.1 mol) is used for reduction of the silanol groups as in synthesis example 3.

The rest of the procedure corresponds to that of synthesis example 3. The following result is obtained:

Methoxy groups are not detectable in the NMR. The residual silanol content is 0.9 percent by weight.
SEC: Mw=6974 g/mol, Mn=2812 g/mol, polydispersity PD=2.48.

According to ²⁹Si NMR, the molar composition of the silicon-containing fraction of the formulation is:
Me₂Si(Vi)O_{1/2}:50.39%
O_{2/2}(Me)Si—C₂H₄—Si(Me)O_{2/2}:19.56%
PhSiO_{3/2}:30.05%

### Synthesis Example 5: Preparation of an Organopolysiloxane Compound of the Formula (I) Having Alkylene and Phenylene Bridges

The synthesis according to synthesis example 2 is repeated, but using the starting materials in the following amounts instead of those in synthesis example 2:
Phenyltrichlorosilane: 422.6 g (=2 mol)
1,2-Bis (dichloromethylsilyl) ethane: 512.0 g (2 mol)
1,4-Bis (dimethoxyphenylsilyl) benzene: 986.2 g (2.4 mol)
Vinyldimethylchlorosilane: 403.7 g (3.35 mol)

In this synthesis, 271.2 g (2.25 mol) of vinyldimethylchlorosilane is added directly to the chlorosilane mixture metered into the initial charge of water in the first step. The remaining 132.6 g (1.1 mol) is used for reduction of the silanol groups as in synthesis example 3.

The rest of the procedure corresponds to that of synthesis example 3. The following result is obtained:

Methoxy groups are not detectable in the NMR. The residual silanol content is 0.9 percent by weight.
SEC: Mw=4974 g/mol, Mn=1966 g/mol, polydispersity PD=2.53.

According to ²⁹Si NMR, the molar composition of the silicon-containing fraction of the formulation is:
Me₂Si(Vi)O_{1/2}:34.49%
O_{2/2}(Me)Si—C₂H₄—Si(Me)O_{2/2}:20.31%
O_{2/2}(Ph)Si—C₆H₄—Si(Ph)O_{2/2}:24.64%
PhSiO_{3/2}:20.56%

### Synthesis Example 6: Preparation of an Organopolysiloxane Compound of the Formula (I) Having Alkylene and Phenylene Bridges

The synthesis according to synthesis example 6 is repeated, but using the starting materials in the following amounts instead of those in synthesis example 6:
1,2-Bis (trimethoxysilyl) ethane: 540.0 g (2 mol)

In this example, no 1,2-bis (dichloromethylsilyl) ethane is used.

The rest of the procedure corresponds to that of synthesis example 6. The following result is obtained:
Methoxy groups are not detectable in the NMR. The residual silanol content is 0.8 percent by weight.
SEC: Mw=5768 g/mol, Mn=2074 g/mol, polydispersity PD=2.78.

According to ²⁹Si NMR, the molar composition of the silicon-containing fraction of the formulation is:
Me₂Si(Vi)O_{1/2}:32.78%
O_{3/2}Si—C₂H₄—SiO_{3/2}:21.01%
O_{2/2}(Ph)Si—C₆H₄—Si(Ph)O_{2/2}:23.48%
PhSiO_{3/2}:22.73%

### Synthesis Example 7: Preparation of an Organopolysiloxane Compound of the Formula (I) Having Alkylene Bridges

The synthesis according to synthesis example 6 is repeated, but using the starting materials in the following amounts instead of those in synthesis example 6:
1,2-Bis (chlorodimethylsilyl) ethane: 580.6 g (2.7 mol)

No 1,2-bis (dichloromethylsilyl) ethane is used.

No 3-trimethoxysilylpropyl methacrylate is used.

The rest of the procedure corresponds to that of synthesis example 3. The following result is obtained:
Methoxy groups are not detectable in the NMR. The residual silanol content is 0.8 percent by weight.
SEC: Mw=5637 g/mol, Mn=1964 g/mol, polydispersity PD=2.87.

According to ²⁹Si NMR, the molar composition of the silicon-containing fraction of the formulation is:
Me₂Si(Vi)O_{1/2}:11.96%
O_{1/2}(Me₂)Si—C₂H₄—Si(Me₂)O_{1/2}:19.56%
PhSiO_{3/2}:68.48%

### Comparative Example 1: Noninventive Organopolysiloxane Synthesis without Bridging SiC-Bonded Units

The syntheses according to synthesis examples 2, 3, and 4 are repeated but, in a departure from synthesis examples 2-4, using no raw materials having bridging units. This means that no 1,4-bis (dimethoxyphenylsilyl) benzene and no 1,2-bis (dichloromethylsilyl) ethane are used.

The amounts indicated for these raw materials are replaced as follows:

In synthesis example 2, no 1,4-bis (dimethoxyphenylsilyl) benzene is used, otherwise the synthesis is carried out unchanged as indicated.

Result: Product designation V1.2

Residual methoxy content not detectable in 1H-NMR. The silanol content is 1.1 percent by weight.

The following molecular weights were determined by SEC (eluent toluene):
Mw=3657 g/mol, Mn=1759 g/mol, polydispersity PD=2.07.

According to ²⁹Si NMR, the molar composition of the silicon-containing fraction of the formulation is:
Me₂Si(Vi)O_{1/2}:14.96%
H₂C═C(CH₃)C(═O)—O—(CH₂)₃—SiO_{3/2}:15.81%
PhSiO_{3/2}:69.23%

In synthesis example 3, the specified amount of 1,4-bis (dimethoxyphenylsilyl) benzene is replaced on a molar equivalent basis by phenyltrichlorosilane. All other information remains unchanged.

Result: Product designation V1.3

Methoxy groups are not detectable in the NMR. The residual silanol content is 1.0 percent by weight.
SEC: Mw=3477 g/mol, Mn=1385 g/mol, polydispersity PD=2.51.

According to 29Si NMR, the molar composition of the silicon-containing fraction of the formulation is:
Me₂Si(Vi)O_{1/2}:11.03%
H₂C═C(CH₃)C(═O)—O—(CH₂)₃—SiO_{3/2}:11.36%
PhSiO_{3/2}:77.61%

In synthesis example 4, the specified amount of 1,4-bis (dimethoxyphenylsilyl) benzene is replaced on a molar equivalent basis by phenyltrichlorosilane. All other information remains unchanged.

Result: Product designation V1.4

Methoxy groups are not detectable in the NMR. The residual silanol content is 0.9 percent by weight.
SEC: Mw=1576 g/mol, Mn=885 g/mol, polydispersity PD=1.78.

According to ²⁹Si NMR, the molar composition of the silicon-containing fraction of the formulation is:
Me₂Si(Vi)O_{1/2}:51.35%
PhSiO_{3/2}:48.65%

### Use Example 1: Use of the Organopolysiloxanes According to Synthesis Examples 1-7 for Producing Metal-Clad Laminates and Comparison with Comparative Examples V1.2, V1.3, and V1.4

The organopolysiloxanes prepared in accordance with synthesis examples 1 to 7 and in accordance with the comparison example were used as binder in order to produce copper-clad laminates having a glass-fiber-reinforced composite layer. The following input materials were used:

Copper foil: 35 μm thick copper foil (285±10 g/m²) from Jiangtong-Yates Copper Foil Co Ltd, having a ten-point mean roughness Rz of ≤8 μm and an arithmetical mean roughness Ra of ≤0.4 μm, purity ≥99.8%.

Glass fiber: E-glass fiber type 1080 E produced by Changzhou Xingao Insulation Materials Co. Ltd. Thickness 0.055±0.012 mm, 47.5±2.5 g/m².

In this example, the organopolysiloxane from synthesis example 1 was used solvent-free, all others were used in the form of a solution in xylene. For the organopolysiloxanes from synthesis examples 4, 5, 6, and 7 and comparative example V1.4, the solutions in each case contained 90% organopolysiloxane and 10% xylene. For the organopolysiloxanes from synthesis examples 2 and 3 and comparative examples V1.2 and V1.3, formulations of 80% organopolysiloxane and 20% xylene were used.

To initiate curing, the organopolysiloxanes were in each case mixed with 1 percent by weight of dicumyl peroxide, which was evenly dispersed in the resin matrix by stirring.

Laminates were produced by bubble-free impregnation, using a bleeder roller, of 30×30 cm glass fiber layers one layer at a time with the respective organopolysiloxane, optionally in the form of a xylene solution. For this, the glass fiber layers were laid on a dimensionally-stable stainless steel flat surface onto which a layer of copper foil had been placed before the first layer of glass fiber had been laid thereon. A total of 3 layers of glass fiber fabric was each time successively impregnated. To remove any solvent present, the impregnated fabrics were dried to constant weight in a vacuum drying oven at 60° C. and 10 mbar. A second layer of copper foil was then placed on top of the impregnated glass fiber layer and another dimensionally stable stainless steel plate laid thereon. The laminate was heated for 120 min at 200° C. and 30 mbar vacuum in a heatable press at 2 MPa pressure. Copper-clad laminates having a total thickness of 260±20 μm are obtained.

The dielectric properties were determined in accordance with IPC TM 650 2.5.5.13 using a Keysight/Agilent E8361A network analyzer by the split-cylinder resonator method at 10 GHz. The values reported in Table 1 were obtained:

| Organopolysiloxane from | Dₖ | D_{f} |
|---|---|---|
| Synthesis example 1 | 2.76 | 0.0022 |
| Synthesis example 2 | 2.98 | 0.0027 |
| Synthesis example 3 | 2.67 | 0.0029 |
| Synthesis example 4 | 2.76 | 0.0023 |
| Synthesis example 5 | 2.89 | 0.0028 |
| Synthesis example 6 | 2.84 | 0.0025 |
| Synthesis example 7 | 2.56 | 0.0026 |
| Comparative example V1.2* | 3.36 | 0.0045 |
| Comparative example V1.3* | 3.25 | 0.0049 |
| Comparative example V1.4* | 3.29 | 0.0048 |

*noninventive

The Dₖ and D_{f} values of the copper-clad laminates obtained using the organopolysiloxane compounds of the formula (I) are markedly lower than the Dₖ and D_{f} values achieved with the organopolysiloxanes from the comparative examples. Since the aim for high-frequency uses is the lowest-possible dielectric loss factor and dielectric constant, the effect of the invention is clearly evident.

### Use Example 2: Use of the Organopolysiloxanes According to Synthesis Examples 1-7 and of the Organopolysiloxanes According to Comparison Example 1 for Producing Metal-Clad Laminates Using Filler

In a departure from use example 1, 49.5% of type Q 033 precipitated silica (manufacturer Suzhou Ginet New Materials Technology Co Ltd, spherical silicon dioxide particles, D₉₉≤3 μm, SiO₂≥99%) were homogeneously incorporated into the resins and resin solutions using a commercially available dissolver. For the resin formulations in which xylene had been used in use example 1, 30% and 40% xylene was respectively used instead of 10% and 20% xylene.

Instead of directly building up the laminate without a prepreg intermediate, this time prepregs were produced by impregnating the glass fiber layers with the resin formulation as individual layers, in each case on a polytetrafluoroethylene film, and then drying them to constant weight in a vacuum drying oven. In each case three layers of impregnated glass fiber fabric thus produced were then laid on top of one another on a copper foil and the stack completed with a layer of copper foil. In analogous manner to use example 1, this multilayer assembly was pressed between two dimensionally stable stainless steel plates in a vacuum press under the conditions specified in example 1 and cured.

The laminates obtained had thicknesses of 290±20 μm.

The laminates obtained gave the measured dielectric properties reported in Table 2:

| Organopolysiloxane from | Dₖ | D_{f} |
|---|---|---|
| Synthesis example 1 | 2.96 | 0.0031 |
| Synthesis example 2 | 2.92 | 0.0033 |
| Synthesis example 3 | 2.79 | 0.0034 |
| Synthesis example 4 | 2.99 | 0.0030 |
| Synthesis example 5 | 3.00 | 0.0034 |
| Synthesis example 6 | 2.89 | 0.0032 |
| Synthesis example 7 | 3.05 | 0.0035 |
| Comparative example V1.2* | 3.56 | 0.0060 |
| Comparative example V1.3* | 3.54 | 0.0063 |
| Comparative example V1.4* | 3.50 | 0.0066 |

*noninventive

The increase in the Dk and Df values is ascribed to additional polarization effects at the interfaces between the precipitated silica and the organopolysiloxanes. However, the production according to the invention of metal-clad laminates with the an organopolysiloxane compound of the formula (I) is successful in this case too and the advantage over noninventive organopolysiloxanes is clearly evident in this case too.

### Use Example 3: Selected Synthesis Examples with Highly Viscous and Solid Materials Via Prepreg

In a departure from use example 2, this time no filler was used. Under these conditions it is possible to produce prepregs only with organopolysiloxanes that dry to a sufficiently tack-free state. Accordingly, for this example only the organopolysiloxanes from synthesis examples 2 to 7 and the organopolysiloxanes V1.2 and V1.3 from comparative example 1 were used. These were used diluted with 10% and 20% xylene, as indicated in use example 1. The organopolysiloxane from synthesis example 1 is nevertheless inventive, because the possibility of producing a tack-free prepreg is then satisfied here too when this is achieved by suitable measures such as filling with suitable fillers or mixing with other organopolysiloxanes or suitable organic polymers. Since these are measures for creating formulations according to the prior art for producing binder formulations for metal-clad laminates, the tackiness of a prepreg produced from a pure organopolysiloxane compounds of the formula (I) without further formulation measures is not in conflict with the subject matter of the invention.

The procedure otherwise corresponds to the procedure described in use example 2.

The laminates obtained had thicknesses of 270±20 μm.

The laminates obtained gave the measured dielectric properties reported in Table 3:

| Organopolysiloxane from | Dₖ | D_{f} |
|---|---|---|
| Synthesis example 2 | 2.96 | 0.0025 |
| Synthesis example 3 | 2.70 | 0.0026 |
| Synthesis example 4 | 2.70 | 0.0025 |
| Synthesis example 5 | 2.85 | 0.0026 |
| Synthesis example 6 | 2.82 | 0.0023 |
| Synthesis example 7 | 2.55 | 0.0027 |
| Comparative example V1.2* | 3.38 | 0.0049 |
| Comparative example V1.3* | 3.30 | 0.0050 |

*noninventive

The Dₖ and D_{f} values of the copper-clad laminates obtained using the organopolysiloxanes of the invention are markedly lower than the Dₖ and D_{f} values achieved with the organopolysiloxanes from the comparative examples. Since the aim for high-frequency uses is the lowest-possible dielectric loss factor and dielectric constant, the effect of the invention is clearly evident.

### Use Example 4: Use of the Organopolysiloxanes According to Synthesis Examples 1-7 and Comparison Example 1 in a Mixture with Organic Polymers for Producing Metal-Clad Laminates

The procedure corresponds essentially to the procedure described in use example 2. In a departure from use example 2, no filler was used.

Instead, organic polymers were mixed with the organopolysiloxanes. The final solvent-free mixtures always contained 30 percent by weight of organopolysiloxane and 70 percent by weight of organic polymers. Organic polymers were triallyl isocyanurate, NORYL SA 9000, an alpha, omega-methacrylate-terminated polyphenylene ether obtained from SABIC, Mn=2500 g/mol, Tg=160° C., and B 3000 from Nippon Soda, a liquid polybutadiene Mn=3200, viscosity at 45° C.=210 poise with more than 85% 1,2-vinyl structures in the polymer chain. The polymers were always used in the same proportion. They were dissolved/dispersed in xylene, with 30 parts by weight of SA 9000, 25 parts by weight of B 3000, and 15 parts by weight of triallyl isocyanurate dispersed with 100 parts by weight of xylene.

The formulation thus obtained was mixed with the solutions of the organopolysiloxanes prepared according to use example 2 such that the specified mixing ratio of 30% organopolysiloxane and 70% organic components was present in the solution obtained. These solutions were then used to produce prepregs as described in use example 2.

The laminates obtained had thicknesses of 290±20 μm.

The laminates obtained gave the measured dielectric properties reported in Table 4:

| With the organopolysiloxane from | Dₖ | D_{f} |
|---|---|---|
| Synthesis example 1* | 2.99 | 0.0029 |
| Synthesis example 2 | 2.63 | 0.0022 |
| Synthesis example 3 | 2.57 | 0.0024 |
| Synthesis example 4 | 2.68 | 0.0021 |
| Synthesis example 5 | 2.66 | 0.0023 |
| Synthesis example 6 | 2.59 | 0.0022 |
| Synthesis example 7 | 2.60 | 0.0023 |
| Comparative example V1.2* | 3.16 | 0.0040 |
| Comparative example V1.3* | 3.01 | 0.0041 |
| Comparative example V1.4* | 3.21 | 0.0042 |

*noninventive

* The formulation of the organopolysiloxane according to synthesis example 1 and the organic components is inhomogeneous, as can be seen from domain formation in an electron microscopic image. Compatibilization could be achieved by increasing the proportion of phenyl groups attached to silicon or by reducing the aromatic proportion in the organic component of the formulation.

The Dₖ and D_{f} values of the copper-clad laminates obtained using the organopolysiloxanes of the invention are markedly lower than the Dₖ and D_{f} values achieved with the organopolysiloxanes from the comparative examples. Since the aim for high-frequency uses is the lowest-possible dielectric loss factor and dielectric constant, the effect of the invention is clearly evident.

1-6. (canceled)

7. A metal-clad laminate comprising crosslinkable, organopolysiloxane compounds of the formula (I)
[O_{3-a/2}RₐSi—Y(SiRₐO_{3-a/2})_{b}]_{c}(R¹SiO_{3/2})_{d}(R₂²SiO_{2/2})ₑ(R₃³SiO_{1/2})_{f}(SiO_{4/2})_{g} (I)
where R may be identical or different and is either a hydrogen radical or a monovalent SiC-bonded organic hydrocarbon radical having 1 to 18 carbon atoms and optionally substituted with heteroatoms,
Y is a divalent to dodecavalent organic radical having 1 to 24 carbon atoms and optionally substituted with heteroatoms, where the radical Y is always attached by a Si—C bond to the silicon atoms connected to each other by the radical Y,
R¹ is independently of one another a bydrogen radical or a SiC-bonded unsaturated C1-C18 hydrocarbon radical that may optionally be substituted with heteroatoms and that optionally may also be attached to the silicon atom via an oxygen atom, where the radicals R¹ may each assume their meaning independently of one another, such that a plurality of radicals R¹ in the organopolysiloxane according to formula (I) may be different radicals from the defined group,
the radicals R² and R³ are independently of one another a hydrogen radical or an optionally unsaturated SiC-bonded C1-C18 hydrocarbon radical that may optionally be substituted with heteroatoms, or a C1-C12 hydrocarbon radical that optionally contains heteroatoms and is attached via an oxygen atom, where the radicals R² and the radicals R³ may each assume their meaning independently of one another, such that a plurality of radicals R² or a plurality of radicals R³ attached to the same silicon atom may be different radicals from the defined group,
where, based on all SiC-bonded radicals Y, R, R¹, R², and R³ as 100 mol %, at least 0.1 mol % must be aliphatically unsaturated radicals,
a is 0. 1 or 2, where the indices a on either side of the group Y may assume their meaning independently of one another, such that different a may independently of one another be different values within the range of values specified,
b is a number having a value from 1 to 11,
c is a value from 0.1 to 0.99,
d is a value from 0 to 0.8,
e is a value from 0 to 0.5,
f is a value from 0.01 to 0.6, and
g is a value from 0 to 0.2, where
c+d+e+f+g=1.

8. The metal-clad laminate as claimed in claim 7, in which the hydrocarbon radicals R, R¹, R², and R³ are selected from methyl, phenyl, vinyl, acryloyloxy, and methacryloyloxy radicals and the acrylic esters or methacrylic esters of unbranched or branched alcohols having 1 to 15 carbon atoms.

9. The metal-clad laminate as claimed in claim 7, in which Y is divalent, trivalent or tetravalent.

10. The metal-clad laminate as claimed in claim 7, comprising formulations that contain organopolysiloxane compounds of the formula (I) and further constituents.

11. The metal-clad laminate as claimed in claim 10, in which the further constituents are selected from hydrosilylation catalyst, initiator for the free-radical polymerization, organic binders, solvents, formulation components, adhesion promoters, curing initiators, catalysts, stabilizers, fillers, inhibitors, flame-retardant additives, crosslinking aids, antioxidants, stabilizers against degradation due to weathering, lubricants, plasticizers, colorants, phosphorescent agents or other agents for the purposes of marking and traceability, and antistats.

12. The metal-clad laminate as claimed in claim 7, in which the metal is copper.
